(19) United States
(12) Patent Application Publication
(10) Pub. No.: US 2015/0249470 A1
(43) Pub. Date: Sep. 3, 2015

(54) COMBINED BLOCK-STYLE ERROR CORRECTION

(71) Applicant: HEWLETT-PACKARD DEVELOPMENT COMPANY, L.P., Houston, TX (US)

(72) Inventors: Ron M. Roth, Palo Alto, CA (US); Pascal Olivier Vontobel, Palo Alto, CA (US)

(21) Appl. No.: 14/417,236

(22) PCT Filed: Oct. 31, 2012
(86) PCT No.: PCT/US2012/062835

§ 371 Date: Jan. 26, 2015

(51) Int. Cl. H03M 13/29; H03M 13/00

(52) U.S. Cl. CPC H03M 13/2906; H03M 13/616

(57) ABSTRACT

In a method for coding information using a coding scheme, a horizontal code is selected. Additionally, a matrix is selected. Encoding information symbols into an array based upon the selected horizontal code is performed. Moreover, encoding the columns of the array based upon the selected matrix is performed.

### BACKGROUND

In coding theory, concatenated codes are a class of error-correcting codes that are derived by combining an inner code and an outer code. Concatenated codes allow for the handling of symbol errors and erasures, and phased burst errors and erasures. However, many applications require a reduced number of parity symbols compared to those provided by concatenated codes.

### BRIEF DESCRIPTION OF THE DRAWINGS

The accompanying drawings, which are incorporated in and form a part of this specification, illustrate and serve to explain the principles of embodiments in conjunction with the description. Unless specifically noted, the drawings referred to in this description should be understood as not being drawn to scale.

FIG. 1 shows a block diagram of ingredients of a coding scheme, in accordance with one embodiment.

FIG. 2A shows a diagram of an example array of information symbols, in accordance with one embodiment.

FIG. 2B shows a diagram of an example encoded array comprising codeword symbols, in accordance with one embodiment.

FIG. 2C shows a diagram of a corrupted array of encoded information symbols, in accordance with one embodiment.

FIG. 3 is a flowchart of a method of encoding information using a coding scheme, in accordance with one embodiment.

FIG. 4 is a flowchart of a method of communicating information reliably, in accordance with one embodiment.

FIGS. 5A-5B are example block diagrams of a method of encoding and decoding using a code, in accordance with one embodiment.

FIG. 6 is a block diagram of a system used in accordance with one embodiment.

### DESCRIPTION OF EMBODIMENTS

Reference will now be made in detail to various embodiments, examples of which are illustrated in the accompanying drawings. While the subject matter will be described in conjunction with these embodiments, it will be understood that they are not intended to limit the subject matter to these embodiments. Furthermore, in the following description, numerous specific details are set forth in order to provide a thorough understanding of the subject matter. In other instances, conventional methods, procedures, objects, and circuits have not been described in detail as not to unnecessarily obscure aspects of the subject matter.

### Notation and Nomenclature

Some portions of the detailed descriptions which follow are presented in terms of procedures, logic blocks, processing and other symbolic representations of operations on data bits within a computer memory. These descriptions and representations are the means used by those skilled in the data processing arts to most effectively convey the substance of their work to others skilled in the art. In the present application, a procedure, logic block, process, or the like, is conceived to be a self-consistent sequence of steps or instructions leading to a desired result. The steps are those requiring physical manipulations of physical quantities. Usually, although not necessarily, these quantities take the form of electrical or magnetic signals capable of being stored, transferred, combined, compared, and otherwise manipulated in a computer system.

It should be borne in mind, however, that all of these and similar terms are to be associated with the appropriate physical quantities and are merely convenient labels applied to these quantities. Unless specifically stated otherwise as apparent from the following discussions, it is appreciated that throughout the present discussions terms such as “selecting”, “encoding”, “transmitting”, “receiving”, “computing”, “applying”, “decoding”, “updating”, or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Furthermore, in some embodiments, methods described herein can be carried out by a computer-usable storage medium having instructions embodied therein that when executed cause a computer system to perform the methods described herein.

### Overview of Discussion

Example techniques, devices, systems, and methods for implementing a coding scheme are described herein. Discussion begins with a brief overview of a coding scheme, and how it addresses phase burst errors and erasures and symbol burst errors and erasures. Next, encoding using the coding scheme is described. Discussion continues with various embodiments used to decode the coding scheme. Next, several example methods of use are described. Lastly, an example computer environment is described.

### Coding Scheme

Transmission and storage systems suffer from different types of errors contemporaneously. For example, a memory cell in a data storage system may be altered by an alpha particle that hits the memory cell. In some cases entire blocks of memory cells may become unreliable due to the degradation of hardware. Such data transmission and data storage systems can be viewed as channels that introduce symbol errors and block errors, where block errors encompass a plurality of contiguous information symbols. It should be understood that as discussed herein, the terms phased burst errors and block errors may be used interchangeably. Moreover, if additional information (e.g., side information) is available, for instance based on previously observed erroneous behavior of a memory cell or cells, a symbol erasure or block erasure is modeled. In an embodiment, erasures differ from errors in that a location of an erasure is known while the location of an error is not. In various embodiments described herein, a coding scheme is operable to perform the task of a concatenated code using fewer parity symbols than a concatenated coding scheme performing the same task.

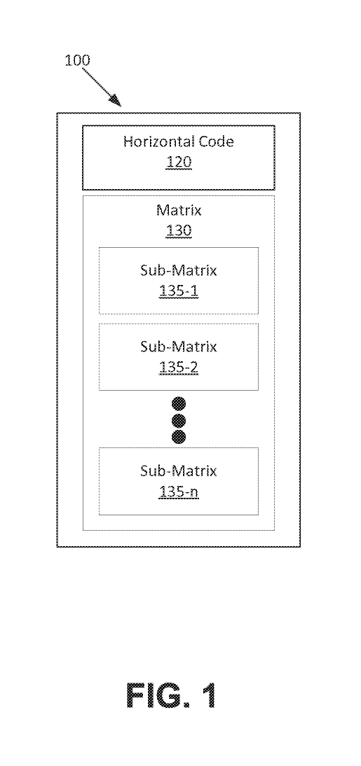

FIG. 1 shows an example coding scheme 100 comprising a horizontal code (C) and a matrix 130 (Hᵢₙ). Matrix 130 comprises a plurality of sub-matrices 135 (i.e., 135-1, 135-2, . . . , 135-n). An outer encoder is derived from the code C, and an inner encoder is derived from the matrix Hᵢₙ from which the vertical encoder. In some examples, these ingredients (i.e., C and Hᵢₙ) and the corresponding encoders are determined off-line and fixed. In an embodiment, code C comprises the parameters n, k, and d, wherein n is the block length of the code C, k is the dimension of C (namely, the number of information symbols, not including the parity symbols), and d is the minimum Hamming distance of code C.

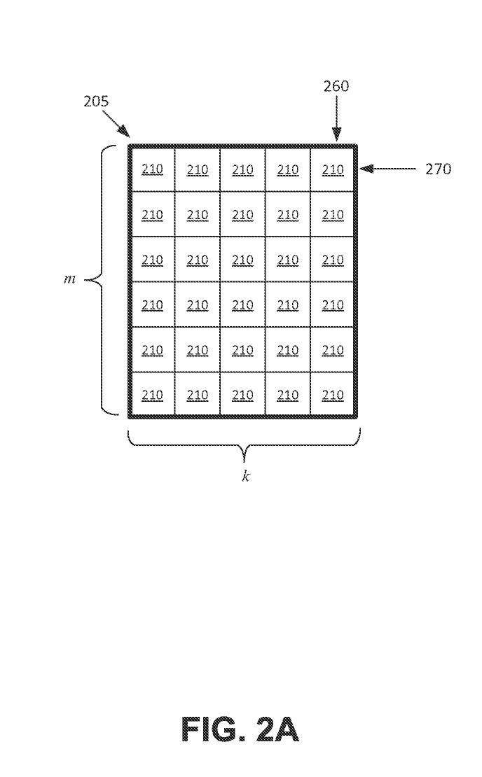

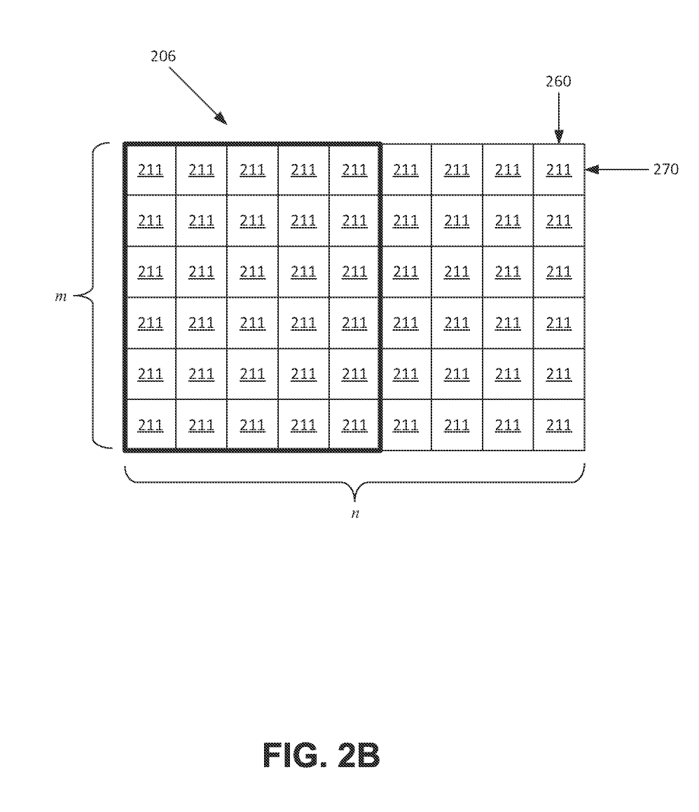

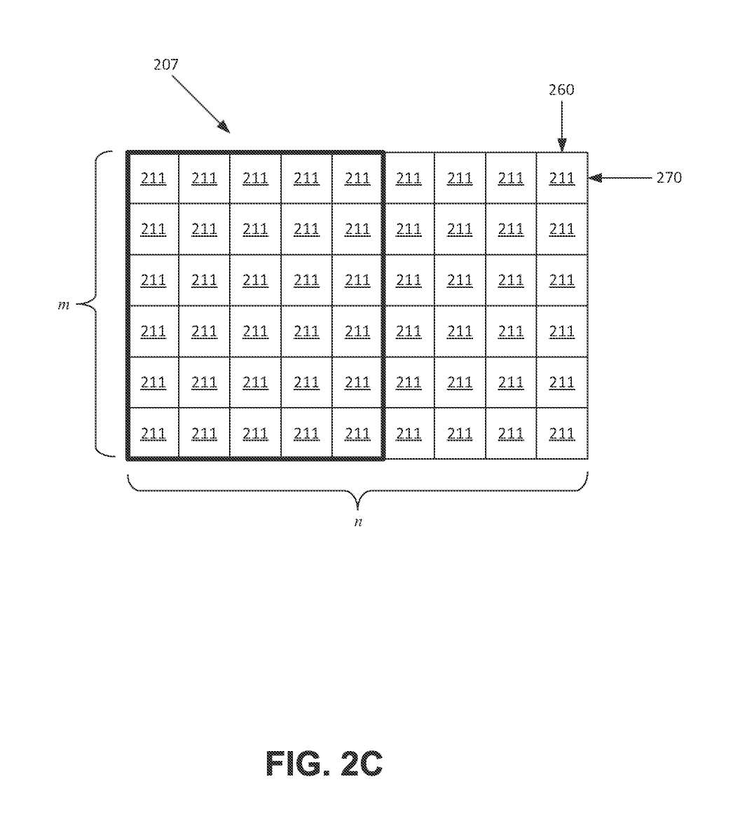

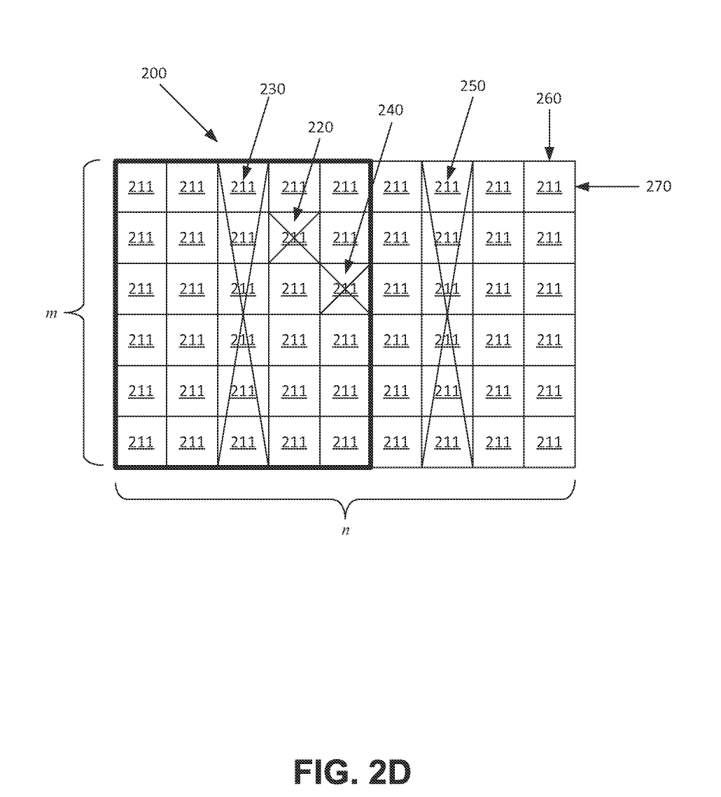

FIG. 2A shows example information symbols 210 comprised within small squares in an array 205. In the example arrays described herein, every small square corresponds to an information symbol in F=GF(q), where q is an arbitrary prime power and GF(q) is the Galois field with q elements. In various examples, q is a small power of 2. In an embodiment, small squares are arranged in the shape of an m×k rectangular array 205.

FIG. 2B shows an encoded array 206 (Γ) of size m×n. In an example, once a code and a matrix 130 have been selected, encoding information symbols may begin using an encoder. As a result, the resulting symbols are referred to as codeword symbols 211. The encoding procedure contains two steps, an outer (also referred to herein as horizontal) encoding step and an inner (also referred to herein as vertical) encoding step. In the outer (also referred to herein as horizontal) encoding step, for every j=1, . . . , m, the k symbols in the j-th row of the first array 205 are encoded with the help of a horizontal encoder for code C; the resulting n symbols are placed in the j-th row of the encoded array 206. In the vertical encoding step, for every i=1, . . . . n, the m symbols in the i-th column are encoded by a bijective mapping derived from the i-th sub-block of Hᵢₙ; the resulting m symbols are placed in the i-th column of the third array 207.

FIG. 2C shows a corrupted array 200 (also referred to as Y) of size m×n which is created when encoded array 206 has passed through a channel that introduced errors into encoded array 206. There are various types of errors. As an example, a symbol error 220 occurs when the content of a small square is altered. A block error 230 (also referred to as a phased burst error) occurs when a plurality of small squares in a column 260 of an array 200 are altered. As similar examples, a symbol erasure 240 occurs when the content of a small square is erased, and a block erasure occurs when a plurality of small squares in a column 260 of an array 200 are erased.

Note that the terms horizontal and vertical (and columns and rows) are terms used to describe a visualization of an array or matrix and may be interchanged (i.e., the visualization of an array may be turned on its side). In various examples decoders may be selected for combinations of errors (220, 230, 240 and 250) that are more efficient than a corresponding decoder for a suitably chosen Reed-Solomon code of length mn over F.

### Encoding

In various embodiments, encoding is performed on information symbols 210 by applying a coding scheme 100 to information symbols 210. In describing the coding scheme 100, it is necessary to describe the channel model and code definition. In an example channel model, an m×n stored (also referred to herein as transmitted or encoded) array 206 (Γ) over F is subject to symbol errors 220, block errors 230, symbol erasures 240, and block erasures 250.

In one example, block errors 230 (also referred to as error type (T1)) are a subset of columns 260 in array 200 that may be indexed by

J⊂ [symbol] n [symbol] , Equation 1

where [symbol] n [symbol] denotes the set of integers {0, 1, . . . , n−1}, and [symbol] a, b [symbol] denotes the set of integers {a, a+1, a+2, . . . , b−1}.

In one example, block erasures 250 (also referred to as (error type (T2)) are a subset of columns 260 in array 200 that may be indexed by

K⊂ [symbol] n [symbol] \J. Equation 2

In one example, symbol errors 220 (also referred to as error type (T3)) are a subset of symbols 210 in array 200 that may be indexed by

L⊂ [symbol] m [symbol] ×( [symbol] n [symbol] \K∪J)). Equation 3

In one example, symbol erasures 240 (also referred to as (error type (T4)) are a subset of symbols 210 in array 200 that may be indexed by

R⊂( [symbol] m [symbol] ×( [symbol] n [symbol] \K))\L. Equation 4

An error matrix (ε) over F represents the alterations that have occurred on encoded array 206 (e.g., alterations that may have occurred during transmission). The received array 200 (referred to herein as γ, or the corrupted message) to be decoded is given by the m×n matrix:

γ= [symbol] +ε Equation 5

In such an example, erasures are seen as errors with the additional side information K and R indicating the location of these errors.

In an example:

τ=|T|,ρ=|K|,θ=|L|, and [symbol] =|R| Equation 6

In other words,

TABLE 1
Types of Errors and Erasures Under Consideration

| | Error | Erasure |
|---|---|---|
| Block | (T1) | (T2) |
| | column 260 set J | column 260 set K |
| | \| J \| = τ | \| K \| = ρ |
| Symbol | (T3) | (T4) |
| | location set L | location set R |
| | \| L \| = [symbol] | \| R \| = [symbol] |

The total number of symbol errors 220 (resulting from error types (T1) and (T3)) is at most mτ+θ and the total number of symbol erasures (resulting from erasure types (T2) and (T4)) is at most m p+ [symbol] . Thus, all error and erasure types (220, 230, 240 and 250 or (T1), (T2), (T3) and (T4)) can be corrected (while occurring simultaneously) while using a code of length m×n of F with a minimum distance of at least

m(2τ+ρ)+2θ+ [symbol] +1. Equation 7

In an example, the code (C) is a linear code (with parameters [n, k, d]) over F. Matrix 130 (Hᵢₙ) is an m×(mn) matrix over F that satisfies the following two properties for a positive integer (δ):
(a) Every subset of δ−1 columns in Hᵢₙ is linearly independent (i.e., Hᵢₙ is a parity-check matrix of a linear code over F of length m×n and minimum distance of at least δ); and
(b)

Hᵢₙ=(H₀|H₁| . . . |Hₙ₋₁) Equation 8
with H₀, H₁, . . . , Hₙ₋₁ being m×m sub-matrices of Hᵢₙ, wherein each Hᵢₙ is invertible over F.

In an example, a codeword is defined to be an m×n encoded matrix (Γ)

=(₀|₁| . . . |ₙ₋₁) Equation 9

over F (where ⱼ stands for column j of Γ) such that each row in

Z=(H_{0 0}|H_{0 1}| . . . |H_{n-1 n-1}) Equation 10

is a codeword of C (horizontal code 120).

In an example, the code C′ is an m-level interleaving of a horizontal code 120 (C), such that an m×n matrix

Z=(Z₀|Z₁| . . . |Zₙ₋₁) Equation 11

over F is a codeword if each row in Z belongs to C. Each column in Z then undergoes encoding by an inner encoder of rate one, wherein the encoder of column j is given by the bijective mapping Zⱼ→Hⱼ⁻¹Zⱼ.

### Decoding

This section will address a plurality of decoders. First, a polynomial-time decoding process for all errors and erasures is presented. Next, specialized decoders are presented. The first specialized decoder corrects (T1), (T2), and (T4) errors and erasures but not (T3) (i.e., symbol erasure 240) errors. By defining the encoder with the help of C and Hᵢₙ, and using the decoders described herein the decoding complexity scales linearly with n³. In various examples, parameters such as m scale with n.

A. Polynomial-Time Decoding

In an embodiment, the horizontal code 120 (C) is a Generalized Reed-Solomon (GRS) code over F and Hᵢₙ is an arbitrary m×(mn) matrix over F that satisfies two properties:
(a) Every subset of δ−1 columns in Hᵢₙ is linearly independent (i.e., Hᵢₙ is a parity-check matrix of a linear code over F of length m×n and minimum distance of at least δ); and
(b)

Hᵢₙ=(H₀|H₁| . . . |Hₙ₋₁) Equation 12

with H₀, H₁, . . . , Hₙ₋₁ being m×m sub-matrices of Hᵢₙ, wherein each Hᵢₙ is invertible over F.

Columns of m×n arrays may be regarded as elements of the extension field GF(q^{m}) (according to some basis of GF(q^{m}) over F). In this example, the matrix Z is a codeword of a GRS code (referred to as C′) over GF(q^{m}), where C′ has the same code locators as a code C.

In an example, Γ is referred to as a codeword and is transmitted as an m×n array. In this example, Y is the received m×n array 200, which may have been corrupted by τ errors of type (T1) (block errors 230) and θ errors of type (T3) (symbol errors 220), wherein

τ≦(d/2)−1 Equation 13

(where d is the minimum distance of an horizontal code 120 (C) as discussed below) and

θ≦(δ−1)/2 Equation 14

First an array 200 an m×n array is computed:

Y=(H_{0 0}|H_{0 1}| . . . |H_{n-1 n-1}) Equation 15

where γ 200 and Y each contains θ+θ≦(d+δ−3)/2 erroneous columns. In other words, Y is a corrupted version of a codeword of C′. In one example a list decoder can be applied for C′ to Y. In various examples, a list decoder returns a list of up to a prescribed number (herein referred to as l) of codewords of C′, and the returned list is guaranteed to contain the correct codeword Γ, provided that the number of erroneous columns 260 in γ 200 does not exceed the decoding radius of C′, which is [nθₗ(d/n)]−1, where θₗ(d/n) is the maximum over sε{1, 2, . . . , l} of the following expression:

$${Θ}_{𝓁 , s} ( d / n ) = 1 - \frac{s + 1}{2 ( 𝓁 + 1 )} - \frac{l}{2 s} ( 1 - \frac{d}{n} ) \qquad Equation 16$$

Thus, if l is such that

nΘₗ(d/n)≧(d+δ−1)/2 Equation 17

then the returned list will contain the correct codeword:

Z=(H_{0 0}|H_{0 1}| . . . |H_{n-1 n-1}) Equation 18

of C′. For each array Z′ in the list the respective array 206 can be computed,

′=(H₀⁻¹Z′₀|H₁⁻¹Z′₁| . . . |Hₙ₋₁⁻¹Z′ₙ₋₁). Equation 19

Only one ′, namely, the transmitted array, can correspond to an error pattern of up to (d/2)−1 block errors and up to (δ−1)/2 symbol errors. In other words, ′ can be computed by checking each computed Z′ against the received array γ 200.

In some examples, the coding scheme 100 can be generalized to handle (T2) and (T4) errors (i.e., block erasures 250 and symbol erasures 240) by applying a list decoder for the GRS code obtained by puncturing C′ to the columns 260 that are affected by erasures. To perform this, the minimum distance (d) is replaced with d−ρ− [symbol] .

B. Decoding (T1), (T2), and (T4) Errors and Erasures but not (T3) (e.g., block errors 230, block erasures 250, and symbol erasures 240 but not symbol errors 220).

In one example, a code C is selected for the case where there are no (T3) errors (i.e., there are no symbol erasures 240, or

|L|=θ=0. Equation 20

In an example, an m×n matrix Γ 206 is transmitted and an m×n matrix

=Γ+ε Equation 21

is received, where

ε=(ε_{κ,j})_{κ∈} [symbol] ₘ [symbol] _{,j∈} [symbol] ₙ [symbol] Equation 22

is an m×n error matrix, with T(⊂ [symbol] n [symbol] ) (and thus where K(⊂ [symbol] n [symbol] )) indexing the columns in which block errors (respectively, block erasures) have occurred, and R(⊂ [symbol] m [symbol] × [symbol] n [symbol] ) is a nonempty set of positions where symbol erasures have occurred. In some examples it is assumed that d, τ(=|T|), and ρ(=|K|) satisfy

2τ+ρ≦d−2 Equation 23

and that [symbol] (=|R|) satisfies

0< [symbol] ≦m Equation 24

In this example Y 200 and E are defined as

Y=(H_{0 0}|H_{0 1}| . . . |H_{n-1 n-1}) Equation 25

and

E=(ε_{h,j})_{h∈} [symbol] ₘ [symbol] _{,j∈} [symbol] ₙ [symbol] =(H_{0 0}|H_{0 1}| . . . |H_{n-1 n-1}) Equation 26

Thus,

Y=Z+E Equation 27

where Z is given by

Z=(H_{0 0}|H_{0 1}| . . . |H_{n-1 n-1}) Equation 28

as discussed above. In particular, in this example, every row of Z is a codeword of a horizontal code 120 taken to be a Generalized Reed-Solomon (GRS) code C=C_{GRS}, the latter being a linear code over F which is defined by the parity-check matrix H_{GRS}=(αⱼⁱ)_{i∈} [symbol] _{d-1} [symbol] _{,j∈} [symbol] ₙ [symbol] , where α₀, α₀, . . . , αₙ₋₁ are distinct elements of F.

Next, denote the elements of R by

R={Kₗ,jₗ)}_{l∈<} [symbol] _{>}. Equation 29

In an example, some l∈< [symbol] >, and the [symbol] univariate polynomial (of degree [symbol] −1) is defined by

$$\begin{matrix}{B}^{( 𝓁 )} ( y ) = {\sum }_{i ∈ 〈 ϱ 〉}^{ } {B}_{i}^{( 𝓁 )} {y}^{i} \\ = {\prod }_{( κ , j ) ∈ ℛ \backslash \{ ( {κ}_{𝓁} , {j}_{𝓁} ) \}}^{ } \frac{1 - {β}_{κ , j} y}{1 - {β}_{κ , j} {β}_{{κ}_{𝓁} , {j}_{𝓁}}^{- 1}}\end{matrix} , 𝓁 ∈ 〈 ϱ 〉 , \qquad Equation 30$$

where β_{κ,j} are distinct and nonzero in F for all κ∈ [symbol] m [symbol] and j∈ [symbol] n [symbol] ; the respective matrix Hᵢₙ=(Hⱼ)_{h∈} [symbol] ₘ [symbol] is then a parity check matrix of an [mn, m (n−1), m+1] GRS code of F, and where

e^{(l)}=(eⱼ^{(l)})_{j∈} [symbol] ₙ

[symbol]

denote row [symbol] −1 of the (m+ [symbol] −1)×n matrix whose entries are given by the coefficients of the bivariate polynomial product B^{(l)}(y)E(y,x), where E(y,x) is the bivariate polynomial in x and y with coefficient of yⁱx^{j} being the entry of E that is indexed by (i,j). As an example,

supp(e^{(l)})⊂T∪K∪{jₗ},l∈< [symbol] > Equation 32

The contribution of a symbol erasure at position (κ, j) in ε to the column Eⱼ(y) of E(y, x) is an additive term of the form

$${ɛ}_{κ , j} \cdot {T}_{m} ( y ; {β}_{κ , j} ) = {ɛ}_{κ , j} \cdot \frac{1 - {( {β}_{κ , j} y )}^{m}}{1 - {β}_{κ , j} y} \qquad Equation 33$$

where for an element ξ∈F the polynomial Tₘ (y; ξ) is defined as

Σ_{i∈} [symbol] ₘ [symbol] ξⁱyⁱ Equation 34

So, if

(κ,j)(κₗ,jₗ) Equation 35

then the product

$${B}^{( 𝓁 )} ( y ) \cdot {ɛ}_{κ , j} \cdot \frac{1 - {( {β}_{κ , j} y )}^{m}}{1 - {β}_{κ , j} y} = {ɛ}_{κ , j} \cdot \frac{{B}^{( 𝓁 )} ( y )}{1 - {β}_{κ , j} y} \cdot ( 1 - {( {β}_{κ , j} y )}^{m} ) \qquad Equation 36$$

is a polynomial in which the powers y [symbol] ⁻¹, y [symbol] , . . . , y^{m-1} have zero coefficients.

At this point in the process, every row in the (m+ [symbol] −1)×n array

Z^{(l)}(y,x)=B^{(l)}(y)Z(y,x) Equation 37

is a codeword of C_{GRS}, where Z(y, x) is the bivariate polynomial in x and y with coefficient of yⁱx^{j} being the entry of Z that is indexed by (i,j). Therefore, by applying a decoder for C_{GRS} to row Q−1 of Z^{(l)} with ρ+1 erasures indexed by K∪{jₗ}, the vector e^{(l)} may be decoded.

In this example, it follows from the definition of e^{(l)} that for every j∈ [symbol] n [symbol] ,

$$( \begin{matrix}{e}_{j}^{( 0 )} \\ {e}_{j}^{( 1 )} \\ ⋮ \\ {e}_{j}^{( ϱ - 1 )}\end{matrix} ) = ( \begin{matrix}{B}_{0}^{( 0 )} & {B}_{1}^{( 0 )} & … & {B}_{ϱ - 1}^{( 0 )} \\ {B}_{0}^{( 1 )} & {B}_{1}^{( 1 )} & … & {B}_{ϱ - 1}^{( 1 )} \\ ⋮ & ⋮ & ⋮ & ⋮ \\ {B}_{0}^{( ϱ - 1 )} & {B}_{1}^{( ϱ - 1 )} & … & {B}_{ϱ - 1}^{( ϱ - 1 )}\end{matrix} ) ( \begin{matrix}{e}_{ϱ - 1 , j} \\ {e}_{ϱ - 2 , j} \\ ⋮ \\ {e}_{0 , j}\end{matrix} ) . \qquad Equation 38$$

In particular,

$$\begin{matrix}{e}_{{j}_{𝓁}}^{( 𝓁 )} = {\sum }_{i ∈ 〈 ϱ 〉}^{ } {B}_{i}^{( 𝓁 )} {\sum }_{κ : ( κ , {j}_{𝓁} ) ∈ ℛ}^{ } {ɛ}_{κ , {j}_{𝓁}} {β}_{κ , {j}_{𝓁}}^{ϱ - 1 - i} \\ = {\sum }_{κ : ( κ , {j}_{𝓁} ) ∈ ℛ}^{ } {ɛ}_{κ , {j}_{𝓁}} {β}_{κ , {j}_{𝓁}}^{ϱ - 1} {B}^{( 𝓁 )} ( {β}_{κ , {j}_{𝓁}}^{- 1} ) \\ = {ɛ}_{{κ}_{𝓁} , {j}_{𝓁}} {β}_{κ , {j}_{𝓁}}^{ϱ - 1} .\end{matrix} \qquad Equation 39$$

Because l∈ [symbol] [symbol] [symbol] was arbitrary, the error values in ε at the positions R may be recovered. I.e.,

ε_{κ}_{ₗ}_{,j}_{ₗ}=eⱼ_{ₗ}^{(l)}β_{κ}_{ₗ}_{,j}_{ₗ}¹⁻ [symbol] ,l∈ [symbol] [symbol] [symbol] . Equation 40

As such, in this example, symbol erasures may be eliminated from E.

In an example, Table 2 summarizes the process described above for a decoding process for (T1), (T2), and (T4) (i.e., block errors 230, block erasures 250, and symbol erasures 240).

TABLE 2
Decoding (T1), (T2), and (T3) Errors and Erasures but not (T3)

Input:

• Array Υ of size m × n over F.
• Set [symbol] of indexes of column erasures.
• Set [symbol] = {(kₗ, jₗ)}_{lε(p)} of positions of symbols erasures.

Steps:

| 1) | Compute the m × (d − 1) syndrome array | | |
|---|---|---|---|
| | | S = (H₀Υ₀\|H₁Υ₁\| . . . \|Hₙ₋₁Υₙ₋₁)H_{GRS}^{T}. | |
| 2) | Compute the modified syndrome array to the unique o × | | |
| | (d − 1) matrix σ that satisfies the congruence | | |
| | | $σ ( x , y ) ≡ 𝒮 ( y , x ) {Π}_{j ∈ 𝒦} ( 1 - {α}_{j} x ) ( mod \{ {x}^{d - 1} , {y}^{e} \} ) .$ | |
| 3) | For every l ε [symbol] o [symbol] do: | | |
| | | a) | Compute row o − 1 in the unique o × (d − 1) matrix σ^{(l)} |
| | | | that satisfies the congruence |
| | | | σ^{(l)}(y, x) ≡ B^{(l)}(y)σ(y,x)(1 − αⱼₗx) |
| | | | (mod{x^{d-1}, y^{o}}), |
| | | | where B^{(l)}(y) is as in (30). |
| | | b) | Decode eⱼₗ^{(l)} (i.e., entry jₗ in e^{(l)}) by applying a decoder |
| | | | for C_{GRS} using row o − 1 in σ^{(l)} as syndrome and |
| | | | assuming that columns indexed by [symbol] ∪ {jₗ} are erased. |
| | | | Compute εₖ_{ₗ}_{,j}_{ₗ} = eⱼ_{ₗ}^{(l)} · βₖ_{ₗ}_{,j}_{ₗ}¹⁻^{o}. |
| | | c) | Update the received array Υ and the syndrome array S |
| | | | by |
| | | | Υ(y, x) ← Υ(y, x) − εₖ_{ₗ}_{,j}_{ₗ} · x^{j}^{ₗ}y^{k}^{ₗ} |
| | | | S(y, x) ← S(y, x) − εₖ_{ₗ}_{,j}_{ₗ} · T_{d-1}(x; αⱼ_{ₗ}) · Tₘ(y; βⱼ_{ₗ}). |
| 4) | For every h [symbol] m [symbol] , apply a decoder for C_{GRS} using row h | | |
| | of S as syndrome and assuming that columns indexed by [symbol] | | |
| | are erased. Let E be the m × n matrix whose rows are the | | |
| | decoded error vectors for all h ε [symbol] m [symbol] . | | |
| 5) | Compute the error array | | |
| | | | ε = (H_{θ}⁻¹E_{θ}\|H₁⁻¹E₁\| . . . \|Hₙ₋₁⁻¹Eₙ₋₁). |

Output:

• Decoded array Υ − ε of size m × n.

C. Decoding (T1), (T2), and (T4) Errors and Erasures and with Restrictions on Errors of Type (T3) (e.g., Block Errors 230, Block Erasures 250, and Symbol Erasures 240 and with Restrictions on Symbol Errors 220).

In one example, a code C is selected (e.g., the code C is guaranteed to work) for the case where there are some restrictions on the symbol error 220 positions ((T3) errors), wherein an example, each column, except for possibly one, contains at most one symbol error. The positions of these errors are determined, thereby reducing the decoding to the case described in Section B, above. These restrictions always hold when |L|≦3 and d is sufficiently large

In an example, the same notation is used except: (1) the set L is not necessarily empty; and (2) R is empty. As above, the number of block errors 230 (τ) and the number of block erasures 250 (ρ) satisfy

2τ+ρ≦d−2 Equation 41

In an example, when

θ=|L|>0, Equation 42

and

L={(κₗ,jₗ)}_{l∈} [symbol] _{θ} [symbol] . Equation 43

In an example, there exists a w∈ [symbol] θ [symbol] such that the values j₀, j₁, . . . j_{w} are all distinct, while

j_{w}=j_{w+1}= . . . =J_{θ-1}. Equation 44

In this example, θ and w satisfies the inequalities

$$\begin{matrix}ϑ \leq \frac{m}{2} , & Equation 45 \\ w + τ + ρ \leq d - 2. & Equation 46\end{matrix}$$

In other words, the number of erroneous columns does not exceed d−1.

In an example, ε_{κ}_{ₗ}ⱼ_{ₗ}≠0 for every l∈ [symbol] θ [symbol] The set {jₗ}_{l∈(w+1)} will be denoted herein as L′. When θ=0, w is defined to be 0 and L′ to be the empty set.

In an example, the modified syndrome σ is the m×(d−1) matrix that satisfies

$$σ ( y , x ) ≡ S ( y , x ) \cdot {\prod }_{j ∈ K} ( 1 - {α}_{j} x ) ( mod {x}^{d - 1} ) , \qquad Equation 47$$

and ˜S is the m×(d−1−ρ) matrix formed by the columns of a that are indexed by [symbol] ρ, d−1 [symbol] . Note that μ=rank (˜S)=rank ((E)_{T∪L′}).

If μ≧2w+2, then the columns that are indexed by L′ are full block errors (230) (i.e., errors of type (T1)), and

2(τ+w+1)+ρ≦d+μ−2. Equation 48

In an example,

μ≦2w+1. Equation 49

For every j∈T∪L′, column Eⱼ, namely, the column of E that is indexed by j, belongs to colspan(˜S), where, colspan(X) is the vector space spanned by the columns of the array X. This holds for j∈L′\{j_{w}}, in which case Eⱼ (in polynomial notation) takes the form

Eⱼ(y)=ε_{κ,j}·Tₘ(y;β_{κ,j}). Equation 50

In an example, the row vectors a₀, a₁, . . . , a_{m-μ-1} form a basis of the dual space of colspan(˜S), and for every i∈ [symbol] m−μ [symbol] , aᵢ(x) denotes herein the polynomial of degree less than m with coefficient vector aᵢ. Note that

a(y)=gcd(a₀(y),a₁(y), . . . ,a_{m-μ-1}(y)); Equation 51

since the aᵢ's are linearly independent,

deg a(y)≦μ. Equation 52

In other words, a(y) has at most μ(≦2w+1) distinct roots in F. For every ξ∈F, the column vector (ξ^{h})_{h∈} [symbol] ₘ [symbol] (also represented as Tₘ(y;ξ)) belongs to colspan(˜S) (and, hence, to colspan(E)_{T∪L′}), if and only if E is a root of a(y). In particular, β_{κ}_{ₗ}_{,j}_{ₗ} is a root of a(y) for every l∈ [symbol] w [symbol] . The root subset

R={(κ,j):a(β_{κ,j})=0} Equation 53

is denoted herein by R, and the polynomial A(v) is defined by

$$A ( y ) = {\sum }_{i = 0}^{n} {A}_{i} {y}^{i} = {\prod }_{( κ , j ) ∈ R} ( 1 - {β}_{κ , j} y ) , \\ where η = \vert R \vert . \qquad Equation 54$$

In an example, the (m−η)×n matrix Ê=(ê_{h,j})_{h∈(m-η),j∈(n)} which is formed by the rows A(y)E(y,x) that are indexed by [symbol] m−n [symbol] . Including,

$${\hat{e}}_{h , j} ( y ) = {\sum }_{i = 0}^{n} {A}_{i} {e}_{h + η - i , j} , h ∈ 〈 m - η 〉 , j ∈ 〈 n 〉 \qquad Equation 55$$

Ŝ is the (m−η)×(d−1−ρ) matrix formed b the rows of A(y)Ŝ(y,x) that are indexed by [symbol] μ,m [symbol] . Therefore, Êⱼₗ(y)=0 for l∈ [symbol] w [symbol] and

$${\hat{E}}_{{j}_{w}} ( y ) = {\sum }_{𝓁 ∈ 〈 w , ϑ 〉} ( {ɛ}_{{κ}_{𝓁} , {j}_{w}} {β}_{{κ}_{𝓁} , {j}_{w}}^{η} A ( {β}_{{κ}_{𝓁} , {j}_{w}}^{η} ) ) \cdot {T}_{m - η} ( y ; {β}_{{κ}_{𝓁} , {j}_{w}}^{η} ) . \qquad Equation 56$$

The number of summands on the right side of Equation 56 is θ−w, and that number is bounded from above by m−2w−1≦m−u≦m−η. This means that Ê_{jw}(y)=0 if and only if A(β_{κ}_{ₗ}_{,j}_{_{w}}⁻¹,j_{w})=0 for all l∈ [symbol] w,θ [symbol] . Moreover,

rank(˜S)=rank((\hat{E})T_{∪{j}_{_{w}}_{}})=μ−η. Equation 57

Next, the following three cases are distinguished.

1. Case 1: η=μ

According to example Equation 57, Ê_{jw}(y)=0, which is equivalent to having A(β_{κ}_{ₗ}_{,j}_{ₗ}⁻¹)=0 for all l∈ [symbol] θ [symbol] . Thus, L⊂R, and the decoding is then reduced to the case described in Section B, above.

2. Case 2: η=μ−1

If Ê_{jw}(y)=0 then L⊂R. Otherwise (according to Equation 57), each column in (˜S) must be a scalar multiple of Ê_{jw}. Note that herein Ê and Ê (as used in some equations), are used interchangeably. The entries of Ê_{jw}, in turn, form a sequence that satisfies the (shortest) linear recurrence

$$\begin{matrix}B ( y ) = {\sum }_{i = 0}^{\vert {R}^{′} \vert} {B}_{i} {y}^{i} = {\prod }_{( κ , j ) ∈ {R}^{′}} ( 1 - {β}_{κ , j} y ) , \\ where & Equation 58 \\ {R}^{′} = \{ {κ}_{𝓁} , {j}_{w} ) \text{:} 𝓁 ∈ 〈 w , ϑ 〉 and A ( {β}_{{κ}_{𝓁}}^{- 1} {j}_{w} ) \neq 0 \} . & Equation 59\end{matrix}$$

This recurrence is uniquely determined, since the number of entries in Ê_{jw}, which is m−η=m−μ+1≧m−2w, is at least twice the degree |R′| (≦θ−w) of B(y). The recurrence can be computed from any nonzero column of (˜S).

From there, L⊂R∪R′, is derived, where

$$\vert R ⋃ {R}^{′} \vert = \vert R \vert + \vert {R}^{′} \vert \leq η + ϑ - w \leq 2 w + ϑ - w \leq ϑ - w \leq m \qquad Equation 60$$

Once again decoding can be reduced to the case in Section B, above.

3. Case 3: η≦μ−2

If Ê_{jw}(y)=0 then (again) L⊂R. Hence, Ê can be decoded. As shown in Equation 56,j=j_{w}, the vector Ê_{jw}(y) can be referred to as a syndrome of the column vector

$${ɛ}_{y}^{*} ( y ) = {\sum }_{κ ∈ 〈 m 〉 : A ( {β}_{κ , j}^{- 1} ) \neq 0} {ɛ}_{κ , j} {y}^{κ} \qquad Equation 61$$

with respect to the following parity-check matrix of a GRS code:

$$\begin{matrix}{H}_{GRS}^{( j )} = {( {v}_{κ , j} {β}_{κ , j}^{h} )}_{h ∈ 〈 m - η 〉 , κ ∈ m} \\ where & Equation 62 \\ {v}_{κ , j} = \{ \begin{matrix}{β}_{κ , j}^{η} A ( {β}_{κ , j}^{- 1} ) & if A ( {B}_{κ , j}^{- 1} ) \neq 0 \\ 1 & otherwise\end{matrix} , & Equation 63\end{matrix}$$

Since the Hamming weight of ε*ⱼ is at most θ−w<(m−η)/2, ε*ⱼ can be decoded uniquely from Êⱼ. Thus, for every K such that A(β_{κ,j}⁻¹)≠0, an error value ε_{K,j} is derived, and subtracted from the respective entry of γ, thereby making R a superset of the remaining symbol errors 220. In an example the above process is applied to every nonzero column in Ê with index j∉K. A decoding failure means that j is not j_{w}, and a decoding success for j≠j_{w} will just cause a coding scheme 100 to incorrectly change already corrupted columns in γ, without introducing new erroneous columns. Again, decoding of γ may proceed as in Section B, above.

Table 3 presents the implied decoding system of a combination of errors of the type (T1), (T2), and (T3) (block errors 230, block erasures 250, and symbol errors 220) provided that the type (T3) errors (symbol errors 220) satisfy requirements (a) and (b) above, including Equation 7. As discussed above, these equations hold when m≦d−ρ and the number of type (T3) errors (symbol errors 220) is at most 3.

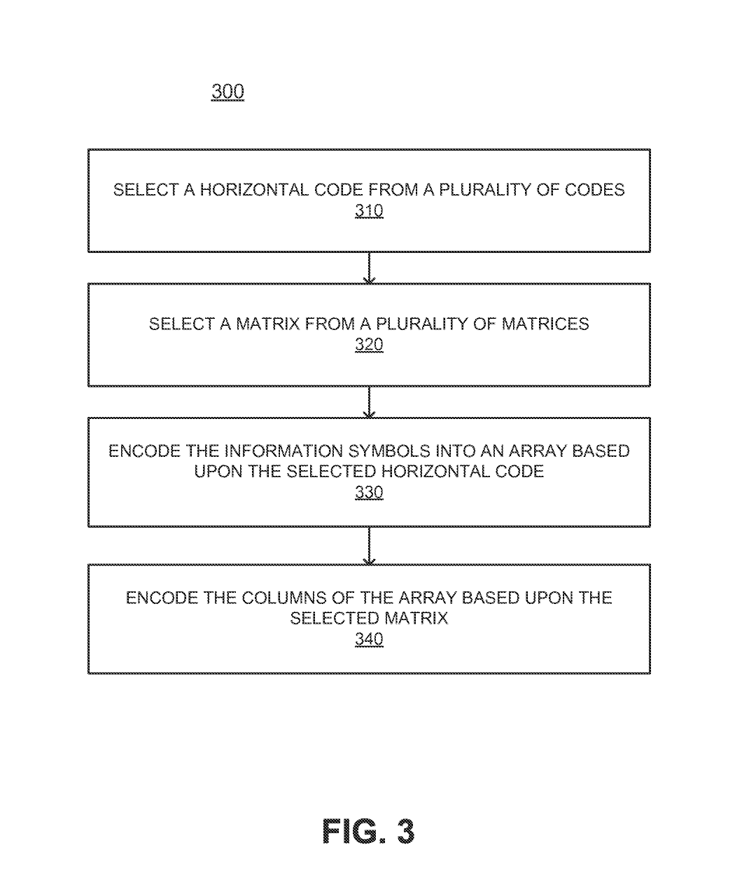

TABLE 3
Decoding (T1), (T2), and (T4) Errors and Erasures, and with restrictions on
the number of (T3) errors. For the sake of simplicity, there are no (T4) Errors

| | |
|---|---|
| Input: | |
| | Array [symbol] of size m × n over F. |
| | Set [symbol] of indexes of column erasures. |
| Steps: | |
| 1) | Compute the m × (d − 1) syndrome array |
| | S = ( H₀ [symbol] ₀ \| H₁ [symbol] ₁ \| . . . \| Hₙ₋₁ [symbol] ₙ₋₁ ) H_{GRS}^{T} . |
| 2) | Compute the m × (d − 1 − p) matrix \tilde{S} formed by the columns |
| | of S(y, x) Π_{jε} [symbol] (1 − αⱼx) that are indexed by (p, d − 1). Let |
| | μ = rank(\tilde{S}). |
| 3) | (Attempt to correct assuming \| [symbol] ′\| ≦ μ/2.) Apply Steps 3- |
| | 4 in Table 4 (with K = [symbol] ) to the modified syndrome array |
| | σ(y, x), to produce an error array E. If decoding is successful, |
| | go to Step 8. |
| 4) | a) Compute the greatest common divisor α(y) of a basis of |
| | the left kernal of \tilde{S}. |
| | b) Compute the set [symbol] and the polynomial A(y) as in (35)- |
| | (36) Let η = \| [symbol] \|. |
| | c) Compute the (m − η) × (d − 1− p) matrix \tilde{S} formed by |
| | the rows of A(y)\tilde{S}(y, x) that are indexed by (η, m). |
| 5) | If η = μ − 1 then do: |
| | a) Compute the shortest linear recurrence B(y) of any |
| | nonzero column in \tilde{S}. |
| | b) Compute the set |
| | [symbol] ′ = {(k, j) : A(B_{k,j}⁻¹) ≠ 0 and B(β_{k,j}⁻¹) = 0} . |
| | c) If \| [symbol] ′\| = deg B(y) and \| [symbol] ′\| ≦ m − η then update |
| | [symbol] ← [symbol] ∪ [symbol] ′. |
| 6) | Else if η ≦ μ − 2 then do: |
| | a) Apply Steps 2-4 in Table 4 with (K = [symbol] ) to the |
| | syndrome array \tilde{S}, to produce an error array Ê. |
| | b)For every index j ∉ [symbol] of a\| nonzero column of Ē do: |
| | i) Apply a decoder for the GRS code with the parity- |
| | check matrix H_{GRS}^{(j)} as in (39)-(40), with \tilde{E}ⱼ as |
| | syndrome, to produce an error vector E ⱼ̅. |
| | ii) If decoding in Step 6(b)i is successful then let E ⱼ̅ = |
| | HⱼE ⱼ̅ and update [symbol] ⱼ ← [symbol] ⱼ − E ⱼ̅ and S(y, x) ← |
| | S(y, x) − E ⱼ̅(y) · T_{d -} ₁ (x; αⱼₗ). |
| 7) | Apply Steps 2-4 in Figure 3 to S, [symbol] , and [symbol] , to produce an |
| | error array E. |
| 8) | Compute the error array |
| | E = ( H₀⁻¹ E₀ \| H₁⁻¹ E₁ \| . . . \| Hₙ₋₁⁻¹ Eₙ₋₁ ) . |
| Output: | |
| | Decoded array [symbol] − E of size m × n. |

TABLE 4
Decoding of Interleaved GRS Codes

Input:

| | |
|---|---|
| • | Array Υ of size m × n over F. |
| • | Set K of size r of indices of column erasures. |

Steps:

| | |
|---|---|
| 1) | Compute the m × (d − 1) syndrome array |
| | S = YH_{GRS}^{T}. |
| 2) | Compute the modified syndrome array to be the unique m × |
| | (d − 1) matrix σ that satisfies the congruence: |
| | σ(y, x) ≡ S(y, x)M(x) (mod x^{d-1}), |
| | where |
| | $M ( x ) = {Π}_{j ∈ 𝒦} ( 1 - {α}_{j} x ) .$ |
| | Let μ be the rank of the m × (d − 1 − r) matrix S̅ formed by |
| | the columns of α that are indexed by (r, d − 1). |
| 3) | Using the Feng-Tzeng algorithm, compute a polynominal λ(x) |
| | of (smallest) degree Δ ≦ (d + μ − r)/2 such that the following |
| | congruence is satisfied for some polynominal w(y, x) with |
| | degₓ w(y, x) < r + Δ: |
| | σ(y, x)λ(w) ≡ w(y, x) (mod x^{d-1}). |
| | If no such λ(x) exists or the computed λ(x) does not divide |
| | Π_{jε(n)}(1 − αⱼx) then declare decoding failure and Stop. |
| 4) | Compute the m × n error array E by |
| | ${E}_{j} ( y ) = \{ \begin{matrix}\frac{- {α}_{j} \cdot w ( y , {α}_{j}^{- 1} )}{{λ}^{′} ( {α}_{j}^{- 1} ) \cdot M ( {α}_{j}^{- 1} )} & if λ ( {α}_{j}^{- 1} ) = 0 \\ \frac{- {α}_{j} \cdot w ( y , {α}_{j}^{- 1} )}{λ ( {α}_{j}^{- 1} ) \cdot {M}^{′} ( {α}_{j}^{- 1} )} & if j ∈ 𝒦 \\ 0 & otherwise \end{matrix} ,$ |
| | where (·)′ deontes formal differentiation. |

Output:

| | |
|---|---|
| • | Decoded array Υ − E of size m × n. |

### Example Methods of Use

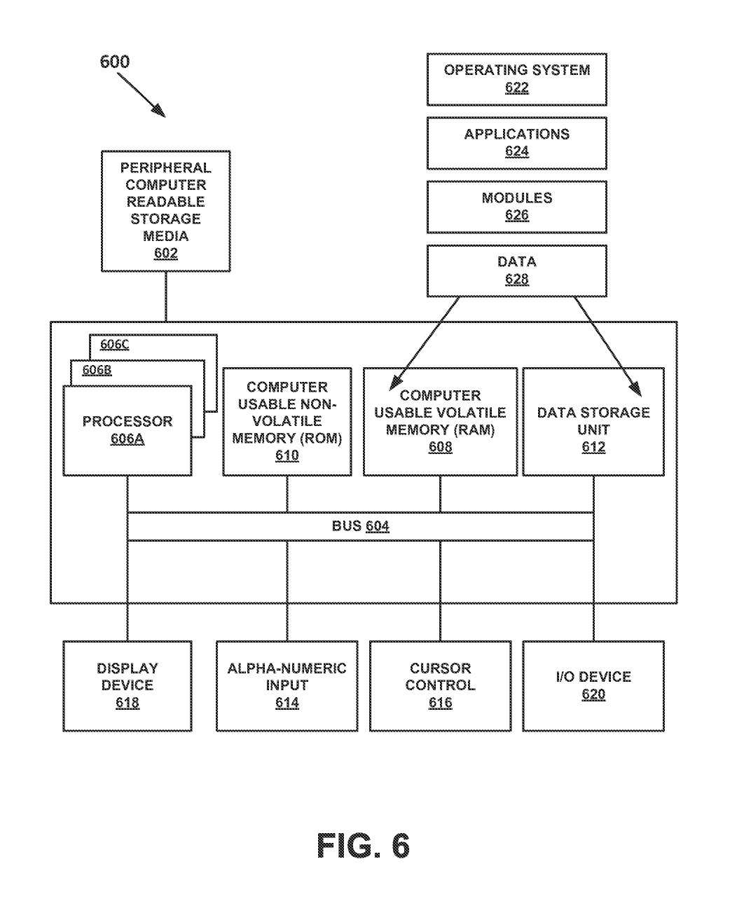

The following discussion sets forth in detail the operation of some example methods of operation of embodiments. FIGS. 3, 4, 5A and 5B illustrate example procedures used by various embodiments. Flow diagrams 300, 400, and 500 include some procedures that, in various embodiments, are carried out by some of the electronic devices illustrated in FIG. 6, or a processor under the control of computer-readable and computer-executable instructions. In this fashion, procedures described herein and in conjunction with flow diagrams 300, 400, and 500 are or may be implemented using a computer, in various embodiments. The computer-readable and computer-executable instructions can reside in any tangible computer readable storage media, such as, for example, in data storage features such as RAM 608, ROM 610, and/or storage device 612 (all of FIG. 6). The computer-readable and computer-executable instructions, which reside on tangible computer readable storage media, are used to control or operate in conjunction with, for example, one or some combination of processor 606A, or other similar processor(s) 606B and 606C. Although specific procedures are disclosed in flow diagrams 300, 400, and 500, such procedures are examples. That is, embodiments are well suited to performing various other procedures or variations of the procedures recited in flow diagrams 300, 400, and 500. Likewise, in some embodiments, the procedures in flow diagrams 300, 400, and 500 may be performed in an order different than presented and/or not all of the procedures described in this flow diagram may be performed, additional operations may be added. It is further appreciated that procedures described in flow diagrams 300, 400, and 500 may be implemented in hardware, or a combination of hardware, with either or both of firmware and software (where the firmware and software are in the form of computer readable instructions).

FIG. 3 is a flow diagram 300 of an example method of encoding information using a coding scheme.

In operation 310, in one example, a horizontal code 120 (C) is selected, and in operation 320, a matrix 130 (Hᵢₙ) is selected.

In an example, A vertical code over F is defined as (C, Hᵢₙ), which consists of all m×n matrices

=(₀|₁| . . . |ₙ₋₁) Equation 64

over F (where j stands for column j of Γ, and is a transmitted array 206) such that each row in

Z=(H_{0 0}|H_{0 1}| . . . |H_{n-1 n-1}) Equation 65

is a codeword in a horizontal code 120 (C).

In an example, the code C′ is an m-level interleaving of C, such that an m×n matrix

Z=(Z₀|Z₁| . . . |Zₙ₋₁) Equation 66

over F is a codeword of C if each row in Z belongs to C. Each column in Z then undergoes encoding by an inner encoder of rate one, wherein the encoder of column j is given by the bijective mapping Zⱼ→Hⱼ⁻¹Zⱼ.

In operation 310, in one example, a horizontal code 120 (C) is selected as a linear [n, k, d] code over F.

In operation 320, in one example, a matrix 130 is selected from a plurality of matrices 130. As discussed above, a matrix 130 (Hᵢₙ) is an m×(mn) matrix over F that satisfies the following two properties a positive integer (δ):
(a) Every subset of δ-1 columns in Hᵢₙ is linearly independent (i.e., Hᵢₙ is a parity-check matrix of a linear code over F of length m×n and minimum distance of at least δ; and
(b)

Hᵢₙ=(H₀|H₁| . . . |Hₙ₋₁) Equation 67

with H₀, H₁, . . . , Hₙ₋₁ being m×m sub-matrices of Hᵢₙ, wherein each Hᵢₙ is invertible over F.

In operation 330, in one example, information symbols 210 are encoded based at least upon the code C. In 340, each column in Z undergoes encoding by an inner encoder of rate one, wherein the encoder of column j is given by the bijective mapping Zⱼ→Hⱼ⁻¹Zⱼ.

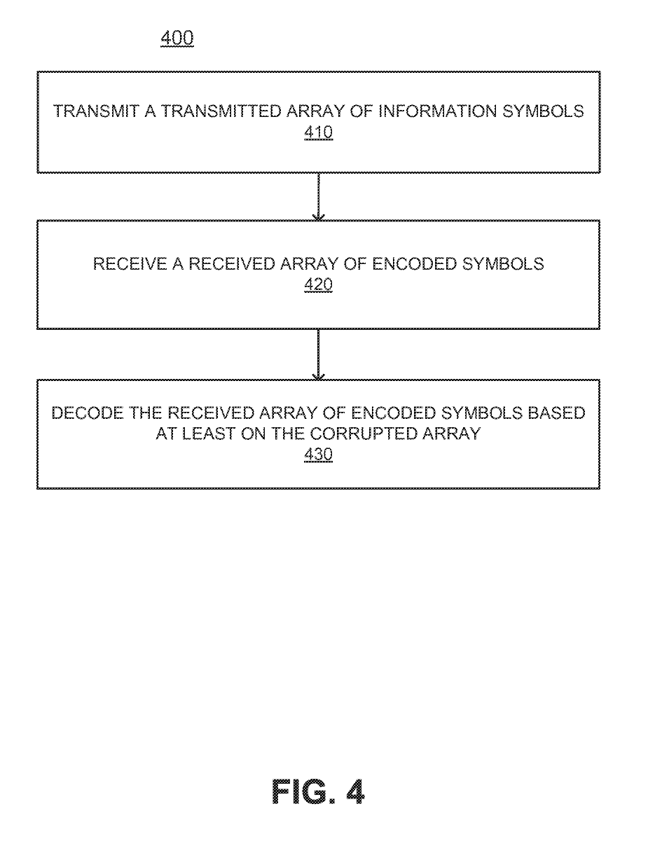

FIG. 4 is a flow diagram 400 of an example method of communicating information reliably.

In operation 410, in various examples, an array of encoded symbols 211 is transmitted. In an example, an array 206 is altered such that encoded symbols 211 in an array 206 become a corrupted array 200 (γ).

In operation 420, in various examples, a received array 200 (γ) of possibly-corrupted encoded symbols 210 is received. The array 200 may be received by a device comprising a decoder.

In an example, an m×n received array 200 (γ)

Y=(H_{0 0}|H_{0 1}| . . . |H_{n-1 n-1}) Equation 68

where received array 200 contains θ+θ≦(d+δ−3)/2 erroneous columns.

In operation 430, in various examples, a received array 200 of encoded symbols 210 is decoded. Using one of the examples described herein for decoding, received array 200 (γ) is decoded back into transmitted array 206 ( ).

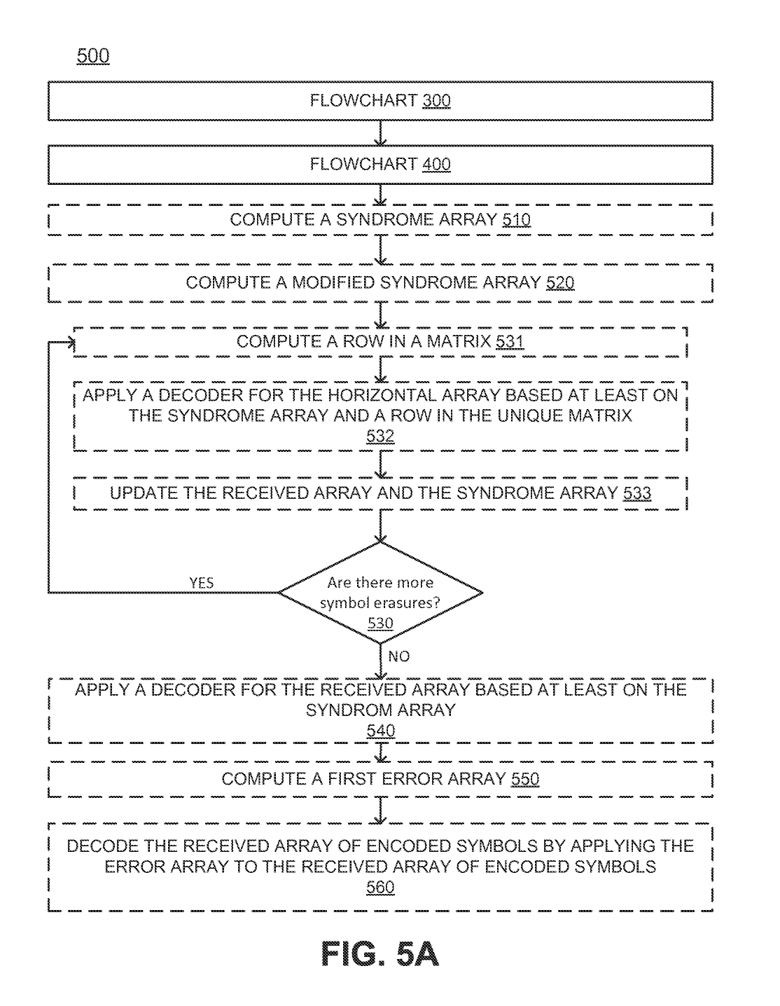

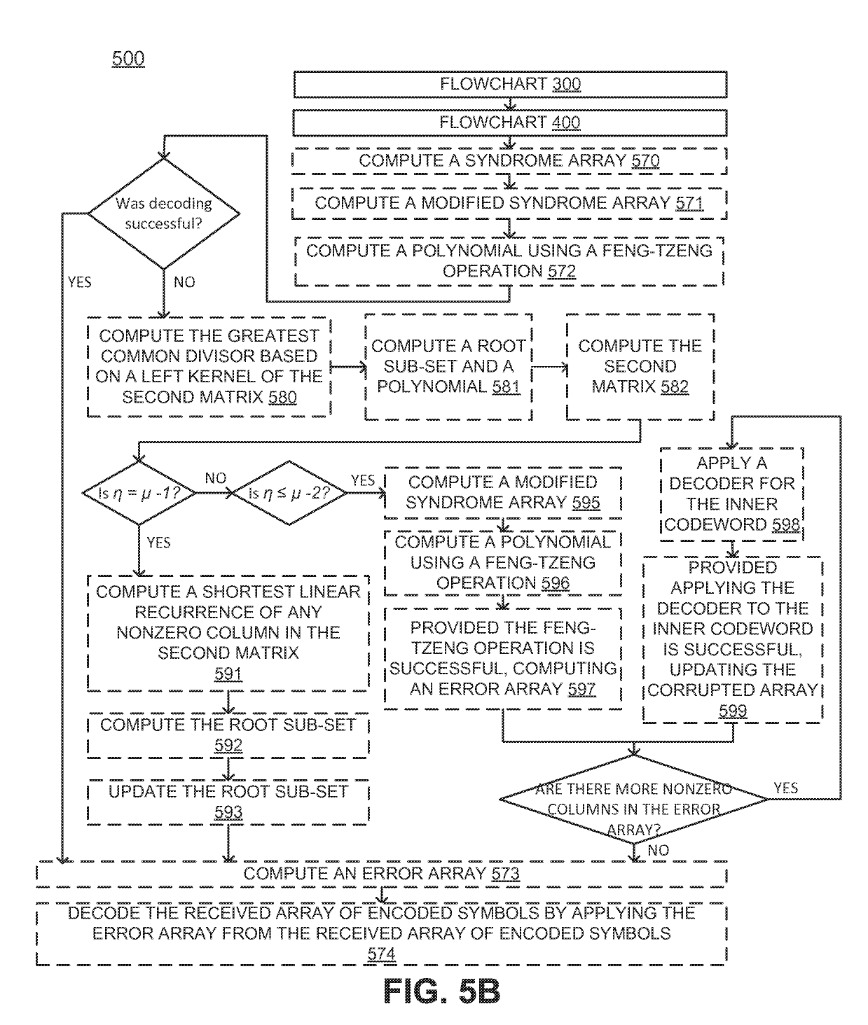

FIG. 5 is a flow diagram 500 of encoding and decoding information symbols 210. Table 2 shows an example of operations 510-560, and Tables 3 and 4 show examples of operations 570-599.

In operation 300, in various examples, information symbols 210 are encoded using a coding scheme 100.

In operation 400, in various examples, encoded symbols 210 are transmitted, received, and decoded.

In operation 510, when included, a syndrome array (S) is computed. For example, the syndrome array may be of size m×(d−1) and shown by

S=(H₀γ₀|H₁γ₁| . . . |Hₙ₋₁γₙ₋₁)H_{GRS}^{T} Equation 69

In operation 520, when included, in various examples, a modified syndrome array is computed. For example, a modified syndrome array is computed to be the unique [symbol] ×(d−1) matrix that satisfies the congruence

$$σ ( y , x ) ≡ S ( y , x ) {\prod }_{j ∈ k} ( 1 - {α}_{j} x ) ( mod \{ {x}^{d - 1} , {y}^{e} \} ) . \qquad Equation 70$$

Note that in various embodiments, the term aⱼ is the same as the ones used above

In operation 530, when included, in various examples, if there are additional symbol erasures 240 in the received array 200 repeat operations 531, 532, and 533. For example, for every l∈< [symbol] >, operations 531, 532, and 533 are performed.

In operation 531, when included, in various examples, a row in a unique row matrix is computed.

$$\begin{matrix}σ ( y , x ) ≡ {B}^{( 𝓁 )} ( y ) ( y , x ) ( 1 - {α}_{jl} x ) ( mod \{ {x}^{d - 1} , {y}^{e} \} ) , \\ where & Equation 71 \\ {B}^{( 𝓁 )} ( y ) = {\sum }_{i ∈ 〈 𝓁 〉} {B}_{i}^{( 𝓁 )} {y}^{i} . & Equation 72\end{matrix}$$

In operation 532, when included, in various examples, a decoder is applied for the horizontal code 120 based at least on the syndrome array and a row in the matrix. For example, eⱼₗ^{(l)} (i.e., entry jₗ in e^{(l)}) by applying a decoder for C_{GRS} (horizontal code 120 utilizing a GRS code) using row [symbol] −1 in σ^{(l)} as syndrome and assuming that columns indexed by K∪{jₗ} are erased. Then

ε_{κ}_{ₗ}_{,j}_{ₗ}=ⱼₗ^{(l)}·β_{κ}_{ₗ}_{,j}_{ₗ}^{1-e}. Equation 73

In operation 533, when included, in various examples, the received array and the syndrome array are updated. For example, the received array (γ) 200 and the syndrome array (S) are updated as in Equations 74 and 75.

γ(y,x)←γ(y,x)−ε_{κ}_{ₗ}_{,j}_{ₗ}·x^{jl}y^{κl} Equation 74

S(y,x)←S(y,x)−ε_{κ}_{ₗ}_{,j}_{ₗ}·T_{d-1}(x;αⱼₗ)Tₘ(y;βⱼₗ) Equation 75

In operation 540, when included, in various examples, a decoder is applied for an inner array based at least on the syndrome array and a row in the matrix. For example, for every h∈ [symbol] m [symbol] decoder is applied for inner linear code 120 (C_{GRS}) using row h of S as syndrome and assuming that columns 260 indexed by K are erased. E is a m×n matrix, where the rows of E are the decoded error vectors for all h∈ [symbol] m [symbol] .

In operation 550, when included, in various examples, a first error array is computed. For example,

ε=(H₀⁻¹E₀|H₁⁻¹E₁| . . . |Hₙ₋₁⁻¹Eₙ₋₁). Equation 76

In operation 560, when included, in various examples, a received array of information symbols 210 is decoded by applying the error array to the received array 200 of encoded symbols 211. For example, transmitted array Γ 206 may be computed by array γ−ε, where γ−ε is an array of size m×n.

In operation 570, when included, in various examples, a syndrome array is computed. For example, the syndrome array (S) may be of size m×(d−1) and shown by

S=(H₀γ₀|H₁γ₁| . . . |Hₙ₋₁γₙ₋₁)H_{GRS}^{T} Equation 77

In operation 571, when included, in various examples, a modified syndrome array is computed. For example, the matrix (˜S) is formed by the columns of

$$S ( y , x ) {\prod }_{j ∈ κ} ( 1 - {α}_{j} x )$$

that are indexed by [symbol] ρ, d−1 [symbol] . In an example μ=rank (˜S).

In operation 572, when included, in various examples, a polynomial is computed using a Feng-Tzeng operation. In various examples, using a Feng-Tzeng process, a polynomial λ(x) is computed of degree Δ≦(d+μ−r)/2 such that the following congruence is satisfied for some polynomial ω(y,x) with degₓ ω(y,x)<r+Δ:

σ(y,x)λ(x)≡ω(x,y)(mod x^{d-1}). Equation 78

If no such λ(x) exists or the computed λ(x) does not divide Πj∈ [symbol] n [symbol] (1−αⱼx) then the decoding has failed and stops. In one example, if the decoding fails flowchart 500 proceeds to step 580. In another example, if the decoding did not fail, flowchart 500 proceeds to step 573.

In operation 573, when included, in various examples, an error array (E) is computed. In an example, an m×n error array (E) is computed by Equation 79:

$${E}_{j} ( y ) = \begin{matrix}\{ \frac{- {α}_{j} \cdot ω ( y , {α}_{j}^{- 1} )}{{λ}^{′} ( {α}_{j}^{- 1} ) \cdot M ( {α}_{j}^{- 1} )} & if λ ( {α}_{j}^{- 1} ) = 0 \\ \{ \frac{- {α}_{j} \cdot ω ( y , {α}_{j}^{- 1} )}{λ ( {α}_{j}^{- 1} ) \cdot {M}^{′} ( {α}_{j}^{- 1} )} & if j ∈ K \\ \{ 0 & otherwise\end{matrix} , \qquad Equation 79$$

where (·)′ denoted formal differentiation.

In operation 574, when included, in various examples, the received array 200 of information symbols 211 is decoded by applying the error array to the received array 200 of information symbols 211. In an example, an error array is computed with equation 80:

ε=(H₀⁻¹E₀|H₁⁻¹E₁| . . . |Hₙ₋₁⁻¹Eₙ₋₁). Equation 80

In an example, a transmitted array 206 is computed by applying the error array to the received array 200:

Γ=γ−ε. Equation 81

In operation 580, when included, in various examples, the greatest common divisor is computed based on a left kernel of a second matrix. For example, as shown in step 4 of Table 3, a greatest common divisor a(y) is computed based at least on the left kernel of (˜S).

In operation 581, when included, in various examples, a root sub-set and a polynomial are computed. For example, the set R and the polynomial A(y) are computed as in Equations 53 and 54. In an example, η=|R|.

In operation 582, when included, in various examples, a second matrix is computed. For example, a (m−η)×(d−1−σ) second matrix (Ŝ) is formed based at least on the rows of A(y)Ŝ(y,x) that are indexed by [symbol] η,m [symbol] .

In an example, if η=μ−1 then operations 591, 592 and 593 are performed. In another example, if η≦μ−1, operations 595, 596, 597, 598 and 599 are performed. One example of these operations can be seen in table 3 at steps 5 and 6.

In operation 591, when included, in various examples, the shortest linear recurrence of any nonzero column in the second matrix is computed. For example, the shortest linear recurrence B(y) is computed for any nonzero column in Ŝ.

In operation 592, when included, in various examples, the root sub-set is computed. For example, the set

R′={(κ,j):A(β_{κ,j}⁻¹)≠0 and A(β_{κ,j}⁻¹)=0}. Equation 82

is computed.

In operation 593, when included, in various examples, the root sub-set is updated. In various examples the root sub-set is not updated. For example, if |R|=deg B(y) and |R′|≦m−η then update R←R∪R′.

As discussed above, in an example, if η≦μ−1, operations 595, 596, 597, 598 and 599 are performed. An example of these options can be seen in table 3 at step 6.

In operation 595, when included, in various examples, a modified syndrome array is computed. For example, a modified syndrome array is computed to be the unique m×(d−1) matrix σ that satisfies the congruence:

$$\begin{matrix}σ ( y , x ) ≡ S ( y , x ) M ( x ) ( mod {x}^{d - 1} ) , \\ where & Equation 83 \\ M ( x ) = {\prod }_{j ∈ K} ( 1 - {α}_{j} x ) . & Equation 84\end{matrix}$$

In an example, μ is the rank of the m×(d−1−r) matrix (˜S) formed by the columns of matrix σ that are indexed by [symbol] r, d−1 [symbol] .

[symbol]

In operation 596, when included, in various examples, a polynomial is computed using a Feng-Tzeng operation. In various examples, using a Feng-Tzeng process, a polynomial λ(x) is computed of degree Δ≦(d+μ−r)/2 such that the following congruence is satisfied for some polynomial ω(y,x) with degₓ ω(y,x)<r+Δ:

σ(y,x)λ(x)≡ω(x,y)(mod x^{d-1}). Equation 85

If no such λ(x) exists or the computed λ(x) does not divide Π_{j∈} [symbol] ₙ [symbol] (1−α₁x) then the decoding has failed and stops. In one example, if the decoding did not fail, flowchart 500 proceeds to step 597.

In operation 597, when included, in various examples, an error array is computed provided the Feng-Tzeng operation is successful. In an example, an m×n error array (Ê) is computed by Equation 79:

$${\hat{E}}_{j} ( y ) = \begin{matrix}\{ \frac{- {α}_{j} \cdot ω ( y , {α}_{j}^{- 1} )}{{λ}^{′} ( {α}_{j}^{- 1} ) \cdot M ( {α}_{j}^{- 1} )} & if λ ( {α}_{j}^{- 1} ) = 0 \\ \{ \frac{- {α}_{j} \cdot ω ( y , {α}_{j}^{- 1} )}{λ ( {α}_{j}^{- 1} ) \cdot {M}^{′} ( {α}_{j}^{- 1} )} & if j ∈ K \\ \{ 0 & otherwise\end{matrix} , \qquad Equation 86$$

where (·)′ denoted formal differentiation.

In an example, steps 598 and 599 are performed for every nonzero column of the error array (Ê). This is shown in step 6(b) of Table 3 (where operation 598 correlates with step 6(b)(i) and step 599 correlates with step 6(b)(ii).

In operation 598, when included, in various examples, a decoder for the inner word 120 is applied. A decoder for a GRS code is applied with the parity-check matrix H_{GRS}^{(j)} as in equations 62 and 63 above (i.e.,

$$\begin{matrix}{H}_{GRS}^{( j )} = {( {v}_{κ , j} {β}_{κ , j}^{h} )}_{h ∈ 〈 m - η 〉 , κ ∈ m} \\ where & Equation 87 \\ {v}_{κ , j} = \begin{matrix}\{ {β}_{κ , j}^{η} A ( {β}_{κ , j}^{- 1} ) & if A ( {B}_{κ , j}^{- 1} ) \neq 0 , \\ \{ 1 & otherwise\end{matrix} ) , & Equation 88\end{matrix}$$

where Êⱼ is a syndrome array, to produce an error vector ε*ⱼ.

In operation 599, when included, in various examples, the corrupted array is updated provided applying the decoder to the inner codeword 210 is successful. For example, provided that operation 598 is successful, E*ⱼ=Hⱼε*ⱼ and a received array is updated. For example, γⱼ←γⱼ−ε*ⱼ and S(y,x)←S(y,x)−E*ⱼ−E*ⱼ·T_{d-1}(x;αⱼₗ).

### Example Computer System

With reference now to FIG. 6, all or portions of some embodiments described herein are composed of computer-readable and computer-executable instructions that reside, for example, in computer-usable/computer-readable storage media of a computer system. That is, FIG. 6 illustrates one example of a type of computer (computer system 600) that can be used in accordance with or to implement various embodiments which are discussed herein. It is appreciated that computer system 600 of FIG. 6 is an example and that embodiments as described herein can operate on or within a number of different computer systems including, but not limited to, general purpose networked computer systems, embedded computer systems, routers, switches, server devices, client devices, various intermediate devices/nodes, stand alone computer systems, media centers, handheld computer systems, multi-media devices, and the like. In one embodiment, computer system 600 may be a single server. Computer system 600 of FIG. 6 is well adapted to having peripheral tangible computer-readable storage media 602 such as, for example, a floppy disk, a compact disc, digital versatile disc, other disc based storage, universal serial bus “thumb” drive, removable memory card, and the like coupled thereto. The tangible computer-readable storage media is non-transitory in nature.

System 600 of FIG. 6 includes an address/data bus 604 for communicating information, and a processor 606A coupled with bus 604 for processing information and instructions. As depicted in FIG. 6, system 600 is also well suited to a multi-processor environment in which a plurality of processors 606A, 606B, and 606B are present. Conversely, system 600 is also well suited to having a single processor such as, for example, processor 606A. Processors 606A, 606B, and 606B may be any of various types of microprocessors. System 600 also includes data storage features such as a computer usable volatile memory 608, e.g., random access memory (RAM), coupled with bus 604 for storing information and instructions for processors 606A, 606B, and 606B. System 600 also includes computer usable non-volatile memory 610, e.g., read only memory (ROM) coupled with bus 604 for storing static information and instructions for processors 606A, 606B, and 606B. Also present in system 600 is a data storage unit 612 (e.g., a magnetic or optical disk and disk drive) coupled with bus 604 for storing information and instructions. System 600 may also include an alphanumeric input device 614 including alphanumeric and function keys coupled with bus 604 for communicating information and command selections to processor 606A or processors 606A, 606B, and 606B. System 600 may also include cursor control device 616 coupled with bus 604 for communicating user input information and command selections to processor 606A or processors 606A, 606B, and 606B. In one embodiment, system 600 may also include display device 618 coupled with bus 604 for displaying information.

Referring still to FIG. 6, display device 618 of FIG. 6, when included, may be a liquid crystal device, cathode ray tube, plasma display device or other display device suitable for creating graphic images and alphanumeric characters recognizable to a user. Cursor control device 616, when included, allows the computer user to dynamically signal the movement of a visible symbol (cursor) on a display screen of display device 618 and indicate user selections of selectable items displayed on display device 618. Many implementations of cursor control device 616 are known in the art including a trackball, mouse, touch pad, joystick or special keys on alphanumeric input device 614 capable of signaling movement of a given direction or manner of displacement. Alternatively, it will be appreciated that a cursor can be directed and/or activated via input from alphanumeric input device 614 using special keys and key sequence commands. System 600 is also well suited to having a cursor directed by other means such as, for example, voice commands. System 600 also includes an I/O device 620 for coupling system 600 with external entities. For example, in one embodiment. I/O device 620 is a modem for enabling wired or wireless communications between system 600 and an external network such as, but not limited to, the Internet.

Referring still to FIG. 6, various other components are depicted for system 600. Specifically, when present, an operating system 622, applications 624, modules 626, and data 628 are shown as typically residing in one or some combination of computer usable volatile memory 608 (e.g., RAM), computer usable non-volatile memory 610 (e.g., ROM), and data storage unit 612. In some embodiments, all or portions of various embodiments described herein are stored, for example, as an application 624 and/or module 626 in memory locations within RAM 608, computer-readable storage media within data storage unit 612, peripheral computer-readable storage media 602, and/or other tangible computer-readable storage media.

Embodiments of the present technology are thus described. While the present technology has been described in particular examples, it should be appreciated that the present technology should not be construed as limited by such examples, but rather construed according to the following claims.

What is claimed is:

1. A method for encoding information symbols using a coding scheme, the method comprising:
selecting a horizontal code from a plurality of codes, wherein said horizontal code are linear codes over a field;
selecting a prescribed length and a prescribed height, wherein said matrix is selected from a plurality of matrices over said field, wherein said matrix comprises a number of rows equaling said prescribed height and a number of columns equaling said prescribed length multiplied by said prescribed height, wherein all column subsets of size less than a prescribed number within said matrix are linearly independent, and wherein a number of square sub-matrices formed by partitioning the column set of said matrix into a number of non-overlapping column subsets are invertible over said field;
encoding said information symbols into an array based upon said selected horizontal code; and
encoding said columns of said array based upon said selected matrix.

2. The method of claim 2, wherein one encoding step constitutes a code which is a prescribed level of interleaving of said horizontal code and consists of arrays such that each row of said arrays belongs to said horizontal code.

3. The method of claim 1, wherein said horizontal code has a prescribed minimum distance.

4. The method of claim 1, wherein said method for encoding information using a coding scheme is operable to correct phased burst errors and symbol errors.

5. A method for communicating information reliably, the method comprising:
transmitting a transmitted array of information symbols;
receiving a received array of encoded symbols, wherein said received array is corrupted by a first type of error, a second type of error, a third type of error, and a fourth type of error, wherein said first type of error is a block error, said second type of error is a block erasure, said third type of error is a symbol error, and said fourth type of error is a symbol erasure;
decoding said received array of encoded symbols based at least on said corrupted array.

6. A method for encoding and decoding a code, the method comprising:
selecting a horizontal code from a plurality of codes, wherein said horizontal codes are linear codes over a field;
selecting a prescribed length and a prescribed height, wherein said matrix is selected from a plurality of matrices over said field, wherein said matrix comprises a number of rows equaling said prescribed height and a number of columns equaling said prescribed length multiplied by said prescribed height, wherein all column subsets of size less than a prescribed number within said matrix are linearly independent, and wherein a number of square sub-matrices formed by partitioning the column set of said matrix into a number of non-overlapping column subsets are invertible over said field;
encoding said information symbols into an array based upon said selected horizontal code; and
encoding said columns of said array based upon said selected matrix.

7. The method of claim 6 wherein said horizontal code is a generalized Reed-Solomon code.

8. The method of claim 6, further comprising:
computing a syndrome array;
computing a modified syndrome array;
applying a decoder for said horizontal code based on at least on said syndrome array;
decoding said received array of information symbols by applying said error array to said received array of encoded symbols.

9. The method of claim 8, further comprising:
computing a row in a matrix;
applying a decoder to a horizontal array based at least on a said syndrome array and a row in said matrix; and
updating said received array and said syndrome array

10. The method of claim 6, further comprising:
computing a syndrome array;
computing a second matrix;
computing a polynomial using a Feng-Tzeng operation;
provided said Feng-Tzeng operation is successful, computing an error array; and
decoding said received array of information symbols by applying said error array to said received array of encoded symbols.

11. The method of claim 10, further comprising:
computing a greatest common divisor based at least on the left kernel of said second matrix;
computing a root sub-set and a polynomial; and
computing said second matrix.

12. The method of claim 10, further comprising:
computing a shortest linear recurrence of any nonzero column in said second matrix;
computing said root sub-set; and
updating said root sub-set.

13. The method of claim 10, further comprising:
computing a modified syndrome array;
computing a polynomial using a Feng-Tzeng operation;
provided said Feng-Tzeng operation is successful, computing an error array;
applying a decoder for said horizontal code;
provided applying said decoder to said horizontal code is successful, updating said corrupted array.
